(19) United States
(12) Patent Application Publication
(10) Pub. No.: US 2003/0061706 A1
(43) Pub. Date: Apr. 3, 2003

(54) Method of making interactive information closure and package

(76) Inventors: Larry Smeyak, Lafayette, IN (US); Timothy Carr, Carmel, IN (US); Mark Powell, Crawfordsville, IN (US); John Ziegler, Carmel, IN (US)

Correspondence Address: WOOD, PHILLIPS, KATZ, CLARK & MORTIMER, 500 W. MADISON STREET, SUITE 3800, CHICAGO, IL, 60661, US

(21) Appl. No.: 10/224,204

(22) Filed: Aug. 20, 2002

Related U.S. Application Data
(60) Provisional application No. 60/318,844, filed on Sep. 13, 2001.

(51) Int. Cl. H01Q 17/00; H05K 13/00; H05K 3/02; H01K 3/22

(52) U.S. Cl. 29/601; 29/600; 29/854; 29/847; 29/848

(57) ABSTRACT

A method of making an interactive information package, including an interactive information closure including a radio frequency identification device, contemplates that a microelectronics assembly be provided by formation on an inside surface of the top wall portion of the closure of the package. After formation of the assembly, it is contemplated that a sealing liner be positioned within the closure so that the microelectronics assembly is positioned between the top wall portion and the sealing liner.

### TECHNICAL FIELD

The present invention relates generally to a method of making an interactive information package comprising a closure and container, with the package including a micro-electronics assembly, and more particularly to a method of making such a package by disposition of the micro-electronics assembly on the inside surface of a top wall portion of the closure of the package.

### BACKGROUND OF THE INVENTION

The development of integrated circuitry has permitted use of such devices in a wide range of applications. Use of such arrangements in a product package comprising a closure and container has a wide variety of applications, including product promotions, storage and dissemination product information including product processing, and quality assurance, including tamper-indication, by monitoring the conditions within the product package. U.S. Patent Application Serial No. 60/291,916, filed May 18, 2001, hereby incorporated by reference, discloses a product package including a closure and container, wherein the closure includes a microelectronics assembly configured for interaction with associated radio frequency “writers” and scanners.

A microelectronics assembly such as disclosed in the above-referenced patent application is configured for radio frequency interaction by the provision of a suitable radio frequency identification (RFID) integrated circuit, an antenna, and one or more inter-connectors operatively connecting the circuit and the antenna. The microelectronics assembly may include one or more micro-sensors, as well as a self-contained power source.

Cost-effective use of such interactive devices in packages including closures and containers requires that the microelectronics assembly be efficiently and economically positioned in the package, preferably adjacent to the inside surface of a top wall portion of the package's closure. In the past, common practice has been to supply microelectronics, and in particular RFID tags, embedded in or attached to a plastic substrate. Such a plastic substrate is typically supplied in large rolls to manufacturers of so-called “smart” products, such as smart credit cards and the like. Suitable machinery has been developed whereby the microelectronics assemblies can be efficiently inserted into products, such as by detachment from the substrate, or alternatively, by insertion of a portion of the substrate along with the microelectronics assembly into the product being manufactured.

The present invention is directed to a method of making an interactive information package, including a closure and container, wherein a microelectronics assembly is formed on the inside surface of the top wall portion of the package's closure for use in association with the contents of the package.

### SUMMARY OF THE INVENTION

A method of making an interactive information closure for a package contemplates molding of a plastic closure having a top wall portion, and an annular depending skirt portion, and forming a microelectronics assembly on the inside surface of the top wall portion. An associated sealing liner can thereafter be positioned within the closure, either by pre-forming a liner and inserting it into the closure, or by molding the sealing liner within the closure.

A method of making an interactive information closure embodying the principles of the present invention contemplates that the microelectronics assembly provided on the inside surface of the top wall portion of a closure include a radio frequency identification (RFID) integrated circuit, an antenna, and one or more interconnections operatively connecting the circuit and the antenna. In one embodiment, the antenna and interconnections are formed directly on the inside surface of the top wall portion, such as by printing the antenna and interconnections on the inside surface with electrically conductive ink. The printing step can be selected from the group consisting of ink jet printing, silk screen printing, and offset printing.

Alternatively, the antenna and interconnections can be formed on the inside surface of the closure by thin film deposition by evaporation or sputtering, with etching of the thin film, or laser machining of the thin film, effected to form the antenna and interconnections.

The present invention further contemplates that the antenna and interconnections of the microelectronics assembly can be formed on the inside surface of the closure by lamination, with either etching or laser machining of the lamination to form the antenna and interconnections of the microelectronics assembly on the inside surface of the closure.

The integrated circuit of the microelectronics assembly can be positioned either active-side-down (sometimes referred to as “flip chip” placement) on the inside surface of the closure, or active-side-up on the inside surface, in accordance with known manufacturing techniques utilizing wire bonding.

In another form of the present invention, the step of forming the microelectronics assembly on the inside surface of the closure includes positioning the integrated circuit of the assembly on the inside surface (typically active-side-up), and forming a planarization layer over the integrated circuit. The method further contemplates forming one or more openings in the planarization layer, and forming the antenna of the assembly on the planarization layer, with interconnections formed through the openings in the layer. The antenna and interconnections can be formed by metal deposition followed by photolithography, with the step of forming the openings in the planarization layer including photolithography or laser machining.

While the present invention contemplates use of pre-manufactured RFID integrated circuits, it is further contemplated that the step of forming the microelectronics assembly on the inside surface of the closure may include actual formation of the integrated circuit, as well as the associated antenna and interconnections. In this aspect of the invention, the integrated circuit is printed with semi-conductor ink and the antenna, and interconnections are printed on the inside surface of the closure with a conductive ink.

As noted, closures formed in accordance with the present invention ordinarily will include a sealing liner positioned within the closure such that the microelectronics assembly is positioned between the top wall portion of the closure and the sealing liner. While use of pre-cut or otherwise pre-formed liners is contemplated, it is within the purview of the present invention that a liner be positioned within the closure by molding the liner within the closure itself.

Other features and advantages of the present invention will become readily apparent from the following detailed description, the accompanying drawings, and the appended claims.

### BRIEF DESCRIPTION OF THE DRAWINGS

FIG. 1 is a diagrammatic view of an interactive information package of the type that can be formed in accordance with the present invention, including a plastic closure and associated container; and

FIG. 2 is a diagrammatic view of a radio frequency integrated circuit system for providing promotional and quality assurance functions.

### DETAILED DESCRIPTION

While the present invention is susceptible of embodiment in various forms, there is shown in the drawings, and will hereinafter be described, a presently preferred embodiment, with the understanding that the present disclosure is to be considered as an exemplification of the invention, and is not intended to limit the invention to the specific embodiments disclosed herein.

The present invention is directed to a method of making an interactive information package including a plastic closure and container, wherein a radio frequency integrated circuit and associated antenna are disposed within the package, preferably by disposition on the interior surface of the package closure. The arrangement of the present package facilitates its use for a variety of applications, including product promotion, storage and dissemination of product information including product processing information, and product quality assurance, including tamper-evidence. Use of packages formed in accordance with the present invention permits efficient inventory control, by permitting product purchases to be efficiently tracked without resorting to optical scanning of bar codes and the like.

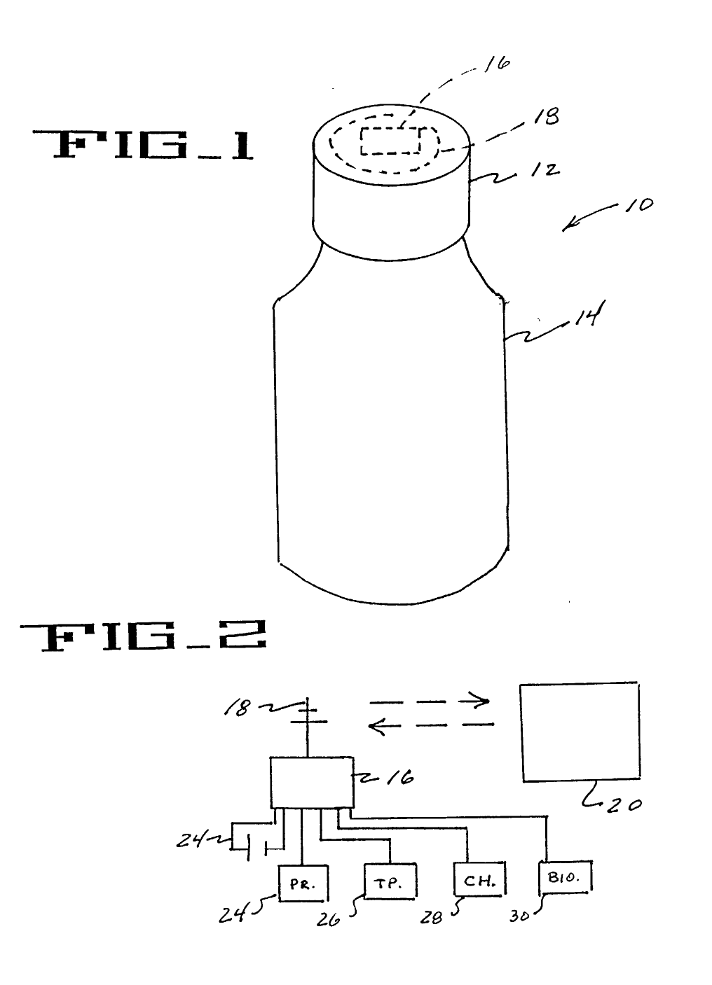

As illustrated in FIG. 1, the package 10 which can be formed in accordance with the present invention comprises plastic closure 12 and an associated container 14 to which the closure can be secured, such as by cooperating, inter-engaged thread formations. Plastic closure 12 can be injection molded or compression molded, with U.S. Pat. No. 4,497,765, hereby incorporated by reference, disclosing a method and apparatus for efficiently compression-molding closures of this type.

The package 10 includes a radio frequency integrated circuit 16 (sometimes referred to as a radio frequency identification (RFID) device or tag) disposed within the package 10, preferably by disposition on or at the interior surface of the closure 12, that is, adjacent the inside surface of a top wall portion of the closure. The arrangement includes an antenna 18 operatively connected to the integrated circuit 16, with the antenna cooperating with the integrated circuit to permit the integrated circuit to be externally powered without physical connection of a power supply thereto. The antenna 18 provides the desired radio frequency interface with an associated radio frequency input/output device 20 (FIG. 2) which can be configured to provide remote input to and/or reading and retrieval of electronic information carried by the integrated circuit 16.

For purposes of the present disclosure, the term microelectronics, and microelectronics assembly, includes, but is not limited to RFID supporting electronics, antenna to support radio frequency communication, micro-sensors, and micro-power sources.

In accordance with the present disclosure, it is contemplated that the integrated circuit 16 and antenna 18, and any associated components, including inter-connectors with the integrated circuit, be positioned within the closure 12 by disposition of the electronic components (referred to herein as a microelectronics assembly) within the closure 12. As will be further described, the microelectronics assembly can be positioned within the closure 12 by formation on the inside surface of the top wall portion thereof. It is contemplated that a sealing liner be provided for the closure, including molding of the liner within the closure after the microelectronics assembly has been formed on the inside surface of the top wall portion.

In the embodiment illustrated in FIG. 1, external powering of the integrated circuit precludes the need for an internal power supply operatively connected to the integrated circuit for providing electrical power thereto. However, for some configurations of the present package (such as providing tamper-evidence indication or capturing continuous historical data on package parameters such as pressure and/or temperature), it can be desirable to provide a compact power supply 22, such as diagrammatically illustrated in FIG. 2, operatively connected to the integrated circuit 16.

The microelectronics assembly of the package can be configured to include one or more different types of compact-size (i.e., micro) sensing devices. Such sensing devices may include, by way of example, a pressure sensor 24, a temperature sensor 26, a chemical sensor 28 for sensing the presence of chemicals such as oxygen, and/or a biological sensor 30 for sensing the presence of microorganisms within the package 10. The configuration of the present package with one or more of the internal sensing devices greatly enhances versatile use of the present package for quality assurance functions, including tamper-evidence, brand protection, and anti-counterfeiting. An array of sensors can be provided for certain applications, with the array preferably integrated with radio frequency integrated circuit 16. The provision of one or more sensors permits direct assessment of the quality state of the packaged goods.

U.S. Patent Application Serial No. 60/291,916, hereby incorporated by reference, further describes use of the package 10 for specific applications.

It is contemplated that the microelectronics assembly used in practicing the present invention is provided in a package including a closure 12 by molding a plastic closure having a top wall portion, and a depending annular skirt portion, and by forming the microelectronics assembly on the inside surface of the top wall portion. The microelectronics assembly includes a radio frequency identification (RFID) integrated circuit, an antenna, and one or more interconnections. Formation of the microelectronics assembly on the inside surface of the top wall portion of the closure includes formation by assembly of the various components on the top wall portion, including in situ formation of one or more of the components.

In one embodiment of the present invention, the microelectronics assembly includes a previously-manufactured RFID integrated circuit, with the antenna and interconnections of the microelectronics assembly formed directly on the inside surface of the top wall portion of the closure 12. In one form of the invention, the antenna and interconnections are printed on the inside surface of the top wall portion with electrically conductive ink. The printing step can be selected from the group consisting of ink jet printing, silk screen printing, and offset printing. It is within the purview of the present invention to form the antenna and interconnections by laser writing, by which metallic conductive pathways are formed by employing a laser which “writes” in a organo-metallic gaseous atmosphere.

Alternatively, the antenna and interconnections of the microelectronics assembly can be formed by thin film deposition by evaporation or sputtering on the inside surface of the top wall of closure 12. The thin film can be etched and/or laser machined to form the antenna and interconnections of the microelectronics assembly.

In a further alternative embodiment, the antenna and interconnections of the microelectronics assembly can be formed by lamination on the inside surface of the top wall portion of closure 12, again with etching and/or laser machining employed to form the antenna and interconnections of the microelectronics assembly on the inside surface.

In conjunction with formation of the antenna and interconnections of the microelectronics assembly on the inside surface of the top wall of the closure 12, it is necessary to position the integrated circuit in operative association with the antenna and interconnections. Disposition of the integrated circuit can be effected by positioning active-side-down on the inside surface of closure 12 with the pads of the integrated circuit directly connected to the antenna or interconnections by soldering, stud-bump bonding or use of a conductive adhesive, or by positioning of the integrated circuit active-side-up on the inside surface of the closure and connecting the pads of the integrated circuit to the antenna or interconnections utilizing wire bonding techniques, depending upon the specific technique employed for formation of the associated antenna and interconnections.

In a further embodiment of the present invention, the step of forming the microelectronics assembly on the inside surface of the top wall portion of closure 12 includes first positioning the integrated circuit on the inside surface of the closure (typically active-side-up), and forming a planarization layer over the integrated circuit. One or more openings are formed in the planarization layer, with the antenna of the assembly formed on the planarization layer, and interconnections formed through the openings in the planarization layer. When the present invention is practiced in this form, the antenna and interconnections can be formed by metal deposition, followed by photolithography, while the step of forming openings in the planarization layer can be effected by either photolithography or laser machining.

For some applications, it can be desirable to actually form an integrated circuit on the inside surface of the top wall portion of closure 12. In practicing this aspect of the present invention, the RFID integrated circuit is formed by printing with semi-conductor ink while the associated antenna, and the interconnections are formed by printing with electrically-conductive ink on the inside surface of the top wall portion.

After the desired microelectronics assembly has been formed on the inside surface of the top wall of closure 12, it is ordinarily necessary to provide the required FDA barrier between the microelectronics and the contents of the closure's package. To this end, a sealing liner is positioned within the closure so that the microelectronics assembly is positioned between the top wall portion of the closure and the sealing liner. The sealing liner may be provided in the form of a pre-formed, disc-shaped sealing liner which is inserted into the closure shell after formation of the electronics assembly on the top wall portion thereof. Alternatively, the step of positioning the sealing liner in the closure can be effected by in situ molding of the sealing liner, such as by compression molding, within the closure.

From the foregoing, it will be observed that numerous modifications and variations can be effected without departing from the true spirit and scope of the novel concept of the present invention. It is to be understood that no limitation with respect to the specific embodiments disclosed herein is intended or should be inferred. The disclosure is intended to cover, by the appended claims, all such modifications as fall within the scope of the claims.

What is claimed is:

1. A method of making an interactive information closure for a package, comprising the steps of:
molding a plastic closure having a top wall portion, and an annular depending skirt portion; and
forming a microelectronics assembly on an inside surface of said top wall portion, said assembly including an RFID integrated circuit, an antenna, and one or more interconnections.

2. A method of making an interactive information closure in accordance with claim 1, including:
forming said antenna and said interconnections directly on the inside surface of said top wall portion.

3. A method of making an interactive information closure in accordance with claim 1, including:
printing said antenna and said interconnections on said inside surface with electrically conductive ink.

4. A method of making an interactive information closure in accordance with claim 3, wherein:
said printing step is selected from the group consisting of ink jet printing, silk screen printing and offset printing.

5. A method of making an interactive information closure in accordance with claim 2, including:
forming said antenna and said interconnections by thin film deposition on said inside surface.

6. A method of making an interactive information closure in accordance with claim 5, including:
etching said thin film to form said antenna and interconnections.

7. A method of making an interactive information closure in accordance with claim 5, including:
laser machining said thin film to form said antenna on interconnections.

8. A method of making an interactive information closure in accordance with claim 2, including:
forming said antenna and said interconnections by lamination on said inside surface.

9. A method of making an interactive information closure in accordance with claim 8, including:
etching said lamination to form said antenna and said interconnections on said inside surface.

10. A method of making an interactive information closure in accordance with claim 8, including:
laser machining said lamination to form said antenna and said interconnections on said inside surface.

11. A method of making an interactive information closure in accordance with claim 1, including:
positioning said integrated circuit active-side-down on said inside surface and connecting the pads of said integrated circuit directly to the antenna or interconnections by soldering, stud-bump bonding or with a conductive adhesive.

12. A method of making an interactive information closure in accordance with claim 1, including:
positioning said integrated circuit active-side-up on said inside surface and connecting the pads of said integrated circuit to the antenna or interconnections utilizing wire bonding.

13. A method of making an interactive information closure in accordance with claim 1, wherein:
said step of forming said microelectronics assembly on said inside surface includes first positioning said integrated circuit on said inside surface, forming a planarization layer over said integrated circuit, forming one or more openings in said planarization layer, forming said antenna on said planarization layer, and forming said interconnections through said openings in said planarization layer.

14. A method of making an interactive information closure in accordance with claim 13, wherein:
said antenna and interconnections are formed by metal deposition followed by photolithography.

15. A method of making an interactive information closure in accordance with claim 13, wherein:
said step of forming openings include photolithography or laser machining.

16. A method of making an interactive information closure in accordance with claim 1, wherein:
said step of forming said microelectronics assembly on said inside surface includes printing said integrated circuit with semiconductor ink, and said antenna, and said interconnections with electrically-conductive ink on said inside surface.

17. A method of making an interactive information closure in accordance with claim 1, including:
positioning a sealing liner within said closure so that said microelectronics assembly is positioned between said top wall portion and sealing liner.

18. A method of making an interactive information closure in accordance with claim 17, wherein:
said positioning step includes molding said sealing liner within said closure.
